(19) United States
(12) Patent Application Publication
(10) Pub. No.: US 2003/0009713 A1
(43) Pub. Date: Jan. 9, 2003

(54) Semiconductor device capable of easily setting test mode during test conducted by applying high voltage

(75) Inventor: Shunsuke Endou, Hyogo (JP)

Correspondence Address: McDERMOTT, WILL & EMERY, 600 13th street, N.W., Washington, DC, 20005-3096, US

(73) Assignee: Mitsubishi Denki Kabushiki Kaisha

(21) Appl. No.: 09/998,326

(22) Filed: Dec. 3, 2001

(30) Foreign Application Priority Data
Jul. 3, 2001 (JP) 2001-202047

(51) Int. Cl. G01R 31/28

(52) U.S. Cl. 714/724

(57) ABSTRACT

A test mode signal generating circuit is provided with a test setting control unit for detecting that an external power supply potential exceeds a predetermined potential. When external power supply potential is a high potential beyond a predetermined standard range, a test mode can be set without setting a signal for test mode entry to be a high potential. Therefore, a semiconductor device which can be set in a test mode by an address key in the case of conducting a test by applying a high power supply voltage can be provided.

### BACKGROUND OF THE INVENTION

1. Field of the Invention

The present invention relates to a semiconductor device and, more particularly, to the configuration of a test mode entry circuit in a semiconductor memory device having a test mode.

2. Description of the Background Art

In a process of manufacturing a dynamic random access memory (DRAM), generally, tests for checking operation are conducted. The tests include an acceleration test conducted by applying a high voltage in high-temperature atmosphere to eliminate an initial defective, and an operation margin checking test. At the time of conducting the tests, a DRAM is instructed to perform a special operation to increase test efficiency. Such a special operation is performed by setting a test mode. The test mode is used by a semiconductor manufacture side, not by the user.

When the test mode is set, the DRAM performs the special operation. In order to prevent the user from setting the DRAM into a test mode by mistake during normal use, an operation of setting the DRAM into the test mode (hereinbelow, called test mode entry) is executed on condition other than operation conditions within the normal standard range.

For example, a high voltage out of the standard range is applied to a predetermined terminal for predetermined time and a combination of address signals corresponding to a test mode is given, thereby realizing a test mode entry.

A conventional test mode entry is made on condition that a high voltage is applied to a predetermined input terminal in most of the tests. That is, by applying a high voltage out of the normal use range to a predetermined terminal in a DRAM for predetermined time, the DRAM is allowed to perform a special operation (test mode operation) which is not specified in the specifications.

FIG. 12 is a circuit diagram showing the configuration related to a test mode entry in a conventional DRAM.

Referring to FIG. 12, the conventional DRAM includes an SVIH comparing circuit 552 for receiving a signal SVIH and an external power supply potential EXVDD, comparing the level of signal SVIH with a predetermined high potential, and outputting a signal BA0S indicative of a comparison result, and a test mode signal outputting circuit 560 for receiving a predetermined combination of address bits A0 to An as an address key signal when all signals BA0S, A7, and MRS are at the H level and outputting a test mode signal TMm.

Test mode signal outputting circuit 560 includes: a NAND circuit 574 for receiving signals BA0S, A7, and MRS; a NAND circuit 576 for receiving the address key signal given by a predetermined combination of address bits A0 to An; and a NAND circuit 578 for receiving outputs of NAND circuits 574 and 576 and outputting test mode signal TMm.

Specifically, as a condition of setting a test mode, signal BA0S outputted from SVIH comparing circuit 552 is used. When signal SVIH is activated to a predetermined high potential, SVIH comparing circuit 552 activates signal BA0S to the H level. It enables test mode signal outputting circuit 560 to accept an address key.

On the other hand, when signal SVIH is lower than the predetermined high potential and is not in an active state, SVIH comparing circuit 552 does not activate signal BA0S. Consequently, test mode signal outputting circuit 560 does not activate test mode signal TMm.

FIG. 13 is an operation waveform chart for explaining an operation of setting the conventional DRAM into a test mode.

Referring to FIG. 13, when mode register set command MRS is given by a combination of the control signals and signal SVIH is in the active state of the high potential at the rising edge of a clock signal CLK at time t1, by setting the address key in the predetermined combination, a test mode is set.

The test mode state is a state where a test mode of carrying out an operation test is accepted when the mode register set command is input and signal SVIH is activated to a predetermined high potential.

Subsequently, when the mode register set command is given again at time t2, signal SVIH is activated to a high potential, and an address key corresponding to a test A is given, the DRAM enters the test A mode.

Further, in the case of conducting a test B in addition to the test A, when the mode register set command is given again at time t3 and signal SVIH is activated to a high potential, the DRAM can enter the test B mode by the address key.

Generally, test modes are combined and a combination is used. In many cases, a plurality of test modes are sequentially set at different timings. By sequentially setting a plurality of test modes, a complicated test can be conducted or a plurality of tests can be simultaneously carried out.

Assuming now that, in FIG. 13, a test mode is set to carry out the test A at time t2, and the test A has to be conducted by setting a power supply voltage to a high voltage. In this case, a problem occurs when signal SVIH is activated at a high potential at time t3.

Specifically, although SVIH comparing circuit 552 as shown in FIG. 12 is provided to make the DRAM recognize that signal SVIH is in an active state of a high potential, a target to be compared is a voltage applied from the outside, for example, external power supply potential EXVDD. According to the contents of a test, the test may be carried out in a state where the voltage to be compared is high. When the power supply voltage is high at time t3, signal SVIH has to be set to a very high active potential or external power supply potential EXVDD to be compared has to be decreased once.

When a potential which is higher than expected at the time of designing is applied as signal SVIH, a load is put on the circuit in the chip and there is the possibility that the reliability of the chip deteriorates. If the voltage to be compared is temporarily decreased, the test time becomes longer. For example, in the case of changing the power supply voltage, a tester needs longer time as compared with the normal case of changing a waveform. The test efficiency therefore deteriorates.

For instance, in a test using a high power supply voltage such as an acceleration test, a voltage to be compared with signal SVIH is high. Consequently, in order to recognize the active state of signal SVIH in such a state, a very high voltage has to be applied to a terminal. When such a very high voltage is applied to a terminal, there is the possibility that the reliability of the chip deteriorates in a process of carrying out a test. Consequently, at the time of setting the test B mode, an operation of temporarily decreasing an internal voltage and, after the DRAM enters the test mode, increasing the internal voltage again is performed. According to a tester, however, time required to change the voltage exerts a large influence on test time, and it causes deterioration in test efficiency.

### SUMMARY OF THE INVENTION

An object of the invention is to provide a semiconductor device having a test mode entry circuit by which a test can be conducted more efficiently on a manufacturer side while suppressing the possibility that a test mode is set by mistake on the user side.

The invention provides, in short, a semiconductor device having a test mode and a normal mode as operation modes, which includes a test mode control circuit.

The test mode control circuit includes: a first comparing circuit comparing a reference potential with a test mode setting potential supplied from the outside; a test setting control unit for generating a test mode entry signal in accordance with an output of the first comparing circuit when the reference potential is lower than a predetermined potential, and generating the test mode entry signal irrespective of an output of the first comparing circuit when the reference potential is at least the predetermined potential; and a test mode signal outputting circuit for outputting a test mode signal indicative of activation of a predetermined test operation in accordance with an output of the test setting control unit.

Therefore, a main advantage of the invention is that, even in the case where a reference potential increases according to a test condition, a test mode can be set easily and a test can be conducted efficiently.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic block diagram showing the configuration of a semiconductor device 1 of a first embodiment of the invention;

FIG. 2 is a block diagram showing the configuration related to a test control of a test mode control circuit 8 in FIG. 1;

FIG. 3 is a circuit diagram showing the configuration of a test mode signal generating circuit 56;

FIG. 4 is a circuit diagram showing the configuration of an SVIH comparing circuit 52 in FIG. 3;

FIG. 5 is a diagram showing the relation between an external power supply potential EXVDD and a signal TE1 in a test setting control unit 58 illustrated in FIG. 3;

FIG. 6 is the plot of voltages corresponding to FIG. 5;

FIG. 7 is an operation waveform chart for explaining a test entry operation of the first embodiment;

FIG. 8 is a circuit diagram showing the configuration of a test mode signal generating circuit 110 in a second embodiment;

FIG. 9 is a circuit diagram showing the configuration of a comparing circuit 114 in FIG. 8;

FIG. 10 is a diagram showing levels of representative nodes in FIG. 9 in the case where external power supply potential EXVDD changes;

FIG. 11 is the plot of voltages corresponding to FIG. 10;

FIG. 12 is a circuit diagram showing the configuration related to a test mode entry in a conventional DRAM; and

FIG. 13 is an operation waveform chart for explaining an operation of setting a test mode in the conventional DRAM.

### DESCRIPTION OF THE PREFERRED EMBODIMENTS

Embodiments of the invention will be described in detail hereinbelow with reference to the drawings. The same reference numeral in the drawings denotes the same or corresponding component.

First Embodiment

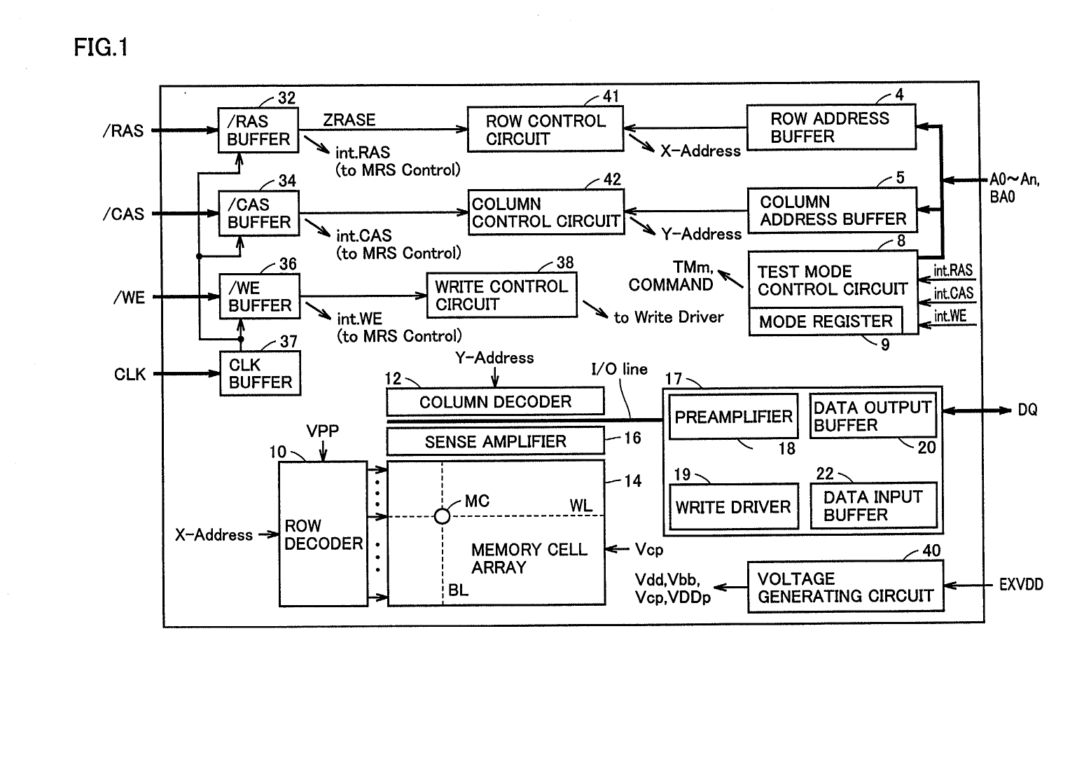

FIG. 1 is a schematic block diagram showing the configuration of a semiconductor device 1 according to a first embodiment of the invention.

Referring to FIG. 1, semiconductor device 1 includes a memory cell array 14 having a plurality of memory cells arranged in a matrix, a row address buffer 4 and a column address buffer 5 which receive address signals A0 to An supplied from the outside, a clock buffer 37 for receiving clock signal CLK from the outside and outputting an internal clock signal to be used in the semiconductor device, and an /RAS buffer 32, a /CAS buffer 34, and a /WE buffer 36 which receive control signals /RAS, /CAS, and /WE, respectively, supplied from the outside synchronously with the internal clock signal.

In memory cell array 14, one word line WL corresponding to a row of memory cells, one bit line BL corresponding to a column of memory cells, and one memory cell provided in correspondence with the intersecting point of word line WL and bit line BL are representatively shown.

Semiconductor device 1 further includes: a test mode control circuit 8 for receiving address signals AO to An and control signals int.RAS, int.CAS, and int.WE synchronized with the clock signal, from /RAS buffer 32, /CAS buffer 34, and /WE buffer 36, respectively, and outputting a control signal including a command signal COMMAND and a test mode signal TMm to each block; and a mode register 9 for holding an operation mode recognized by test mode control circuit 8.

Test mode control circuit 8 includes a not-illustrated bank address decoder for decoding internal bank address signal int.BA0 and a not-illustrated command decoder for receiving and decoding control signals int.RAS, int.CAS, and int.WE.

Semiconductor device 1 further includes: a row control circuit 41 for receiving an output of row address buffer 4 and a signal ZRASE output from /RAS buffer 32 and outputting an address signal X-Address for specifying a row in memory cell array 14; a row decoder 10 for selecting a row in memory cell array 14 in accordance with address signal X-Address; a column control circuit 42 for receiving an output of column address buffer 5 and an output of /CAS buffer 32 and outputting an address signal Y-Address for specifying a column in memory cell array 14; and a column decoder 12 for selecting a column in memory cell array 14 in accordance with address signal Y-Address.

Semiconductor device 1 further includes: a sense amplifier 16 for detecting and amplifying data of memory cells connected to the selected row in memory cell array 14; and a data input/output circuit 17 for transmitting/receiving data to/from the selected memory cell via an I/O line.

Data input/output circuit 17 includes a data input buffer 22 for receiving write data from a data input/output terminal, a write driver 19 for amplifying the write data and transmitting the amplified data to the selected memory cell, a preamplifier 18 for amplifying data read from the selected memory cell, and a data output buffer 20 for driving the data input/output terminal in accordance with an output of preamplifier 18.

Semiconductor device 1 further includes a write control circuit 38 for activating write driver 19 in accordance with an output of /WE buffer 36.

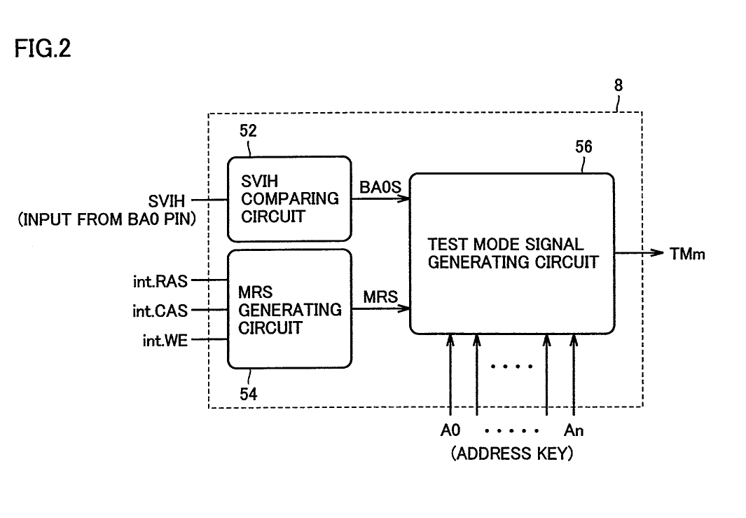

FIG. 2 is a block diagram showing the configuration regarding test control of test mode control circuit 8 in FIG. 1.

Referring to FIG. 2, test mode control circuit 8 includes: an SVIH comparing circuit 52 for detecting an active state of signal SVIH input via a terminal to which bank address signal BA0 is supplied by a comparing operation; an MRS generating circuit 54 for detecting a mode register set command in accordance with a combination of control signals int.RAS, int.CAS, and int.WE and outputting a signal MRS; and a test mode signal generating circuit 56 for outputting test mode signal TMm in accordance with signals BA0S and MRS and an address key given by a combination of address signal bits A0 to An.

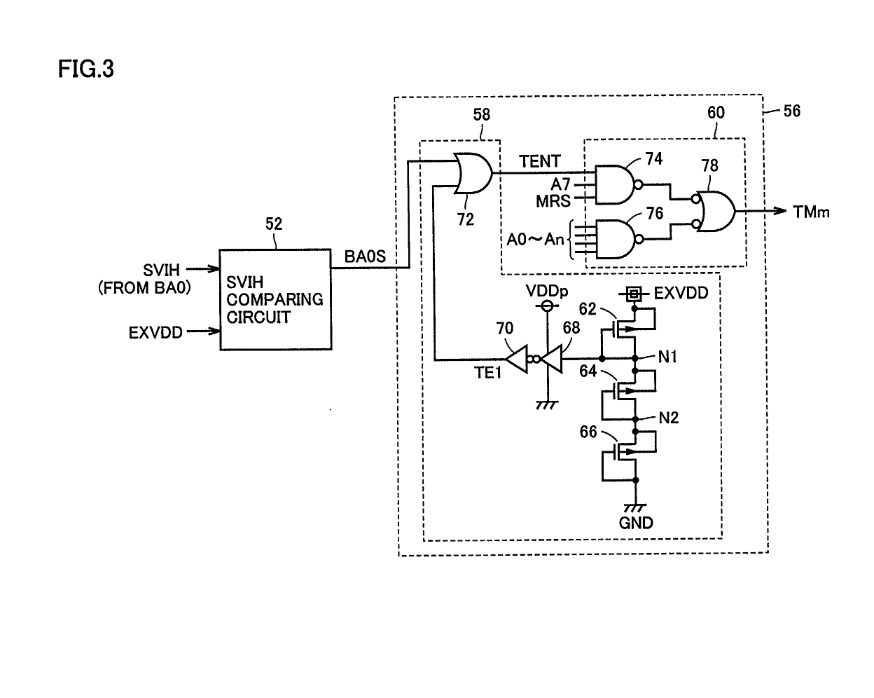

FIG. 3 is a circuit diagram showing the configuration of test mode signal generating circuit 56.

Referring to FIG. 3, SVIH comparing circuit 52 receives signal SVIH supplied via the terminal to which bank address BA0 is given and external power supply potential EXVDD, compares the received signals, and outputs signal BA0S.

Test mode signal generating circuit 56 includes: a test setting control unit 58 for outputting a signal TENT in accordance with signal BA0S and external power supply potential EXVDD; and a test mode signal outputting circuit 60 for outputting test mode signal TMm in accordance with signals TENT, A7, and MRS and the address key.

Test setting control unit 58 includes P-channel MOS transistors 62 to 66 which are connected in series so as to form diodes between a node to which external power supply potential EXVDD is supplied and a ground node.

A connection node of P-channel MOS transistors 62 and 64 connected in series will be referred to as a node N1. A connection node of P-channel MOS transistors 64 and 66 connected in series will be referred to as a node N2.

The back gate of P-channel MOS transistor 62 is connected to the node to which external power supply potential EXVDD is supplied. The gate of P-channel MOS transistor 62 is connected to node N1.

The back gate of P-channel MOS transistor 64 is connected to node N1. The gate of P-channel MOS transistor 64 is connected to node N2.

The back gate of P-channel MOS transistor 66 is connected to node N2. The gate of P-channel MOS transistor 66 is connected to the ground node.

Test setting control unit 58 further includes an inverter 68 whose input terminal is connected to node N1, an inverter 70 for receiving and inverting an output of inverter 68 and outputting a signal TE1, and an OR circuit 72 for receiving signals BA0S and TE1 and outputting signal TENT.

Test mode signal outputting circuit 60 includes a NAND circuit 74 for receiving signals TENT, A7, and MRS, a NAND circuit 76 for receiving a predetermined combination of the address key, and a NAND circuit 78 for receiving outputs of NAND circuits 74 and 76 and outputting test mode signal TMm.

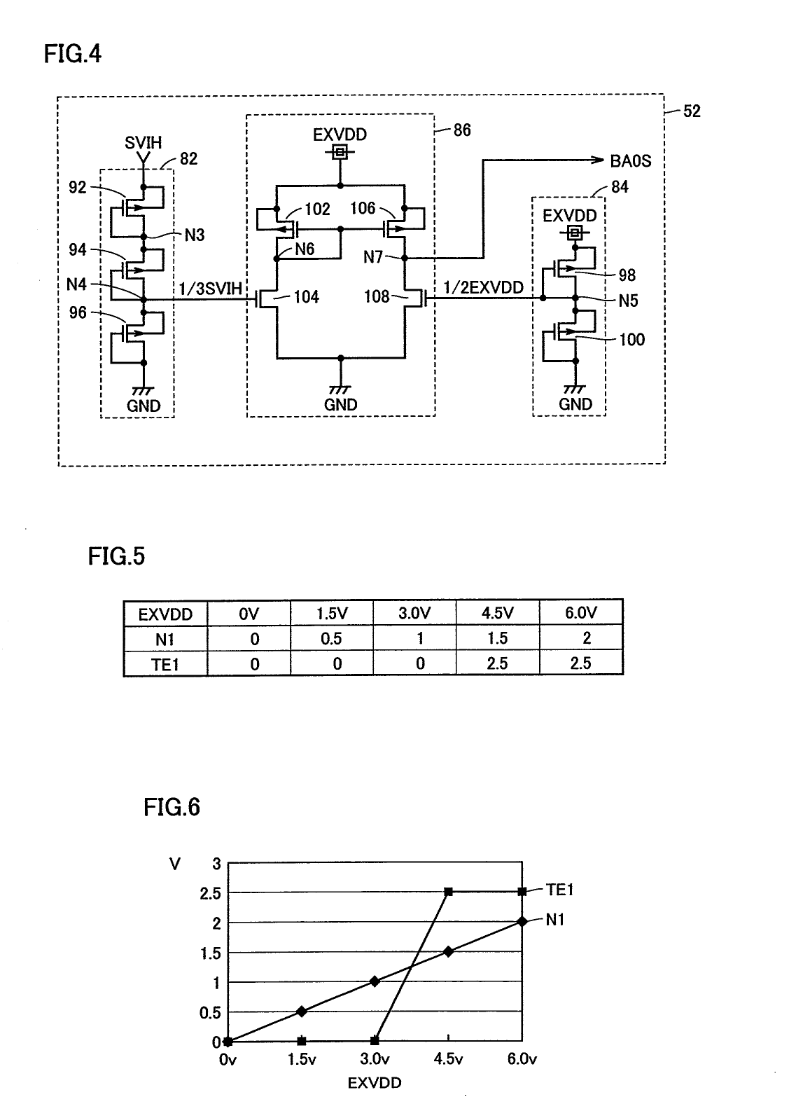

FIG. 4 is a circuit diagram showing the configuration of SVIH comparing circuit 52 in FIG. 3.

Referring to FIG. 4, SVIH comparing circuit 52 includes: a potential down converting circuit 82 for receiving and dropping signal SVIH and outputting a signal 1/3SVIH; a potential down converting circuit 84 for receiving and dropping external power supply potential EXVDD and outputting a signal 1/2EXVDD; and a comparing circuit 86 for comparing signals 1/3SVIH and 1/2EXVDD and outputting a comparison result signal BA0S.

Potential down converting circuit 82 includes: a P-channel MOS transistor 92 having a source and a back gate connected to the node to which signal SVIH is supplied and a gate and a drain connected to a node N3; a P-channel MOS transistor 94 having a source and a back gate connected to node N3 and a gate and a drain connected to a node N4; and a P-channel MOS transistor 96 having a source and a back gate connected to node N4 and a gate and a drain connected to the ground node. Signal 1/3SVIH is output from node N4.

Potential down converting circuit 84 includes: a P-channel MOS transistor 98 having a source and a back gate connected to the node to which external power supply potential EXVDD is supplied and a gate and a drain connected to a node N5; and a P-channel MOS transistor 100 having a source and a back gate connected to node N5 and a gate and a drain connected to the ground node. Signal 1/2EXVDD is output from node N5.

Comparing circuit 86 includes: a P-channel MOS transistor 102 having a source and a back gate connected to the node to which external power supply potential EXVDD is supplied and a gate and a drain connected to a node N6; an N-channel MOS transistor 104 connected between node N6 and the ground node, and receiving signal 1/3SVIH by its gate; a P-channel MOS transistor 106 having a source and a back gate connected to the node to which external power supply potential EXVDD is supplied, a gate connected to node N6, and a drain connected to a node N7; and an N-channel MOS transistor 108 connected between node N7 and the ground node, and receiving signal 1/2EXVDD by its gate.

Although FIG. 4 shows the circuit for dividing signal SVIH to ⅓ and dividing external power supply potential EXVDD to the half as an example of the potential down converting circuit, a dividing ratio of the potential of signal SVIH and external power supply potential EXVDD is determined according to the operating condition at the time of setting the test mode.

FIG. 5 is a diagram showing the relation between external power supply potential EXVDD and signal TE1 in test setting control unit 58 illustrated in FIG. 3.

FIG. 6 is the plot of the voltages corresponding to those in FIG. 5.

Referring to FIGS. 5 and 6, the potential at node N1 becomes the potential of ⅓ of external power supply potential EXVDD by ON-state resistance of P-channel MOS transistors 62, 64, and 66 illustrated in FIG. 3. A case where a threshold voltage of inverter 68 is set around 1.25V is shown here. Inverter 68 receives a power supply potential VDDp for a peripheral circuit from voltage generating circuit 40 in FIG. 1. Power supply potential VDDp is stabilized by voltage generating circuit 40. Therefore, even in the case where external power supply potential EXVDD fluctuates beyond the standard range, an almost constant potential can be maintained.

First, when external power supply potential EXVDD is 0V, the potential at node N1 is 0V and the level of output signal TE1 is 0V.

When external power supply potential EXVDD is 1.5V, the potential at node N1 is 0.5V and the level of output signal TE1 is 0V.

When external power supply potential EXVDD is 3.0V, the potential at node N1 is 1V and the level of output signal TE1 is 0V.

When external power supply potential EXVDD is 4.5V, the potential at node N1 is 1.5V. The potential exceeds the threshold voltage of inverter 68, so that output signal TE1 becomes 2.5V which is at the H level.

When external power supply potential EXVDD is 6.0V, the potential at node N1 is 2V. Since the potential similarly exceeds the threshold voltage of inverter 68, output signal TE1 becomes 2.5V which is at the H level.

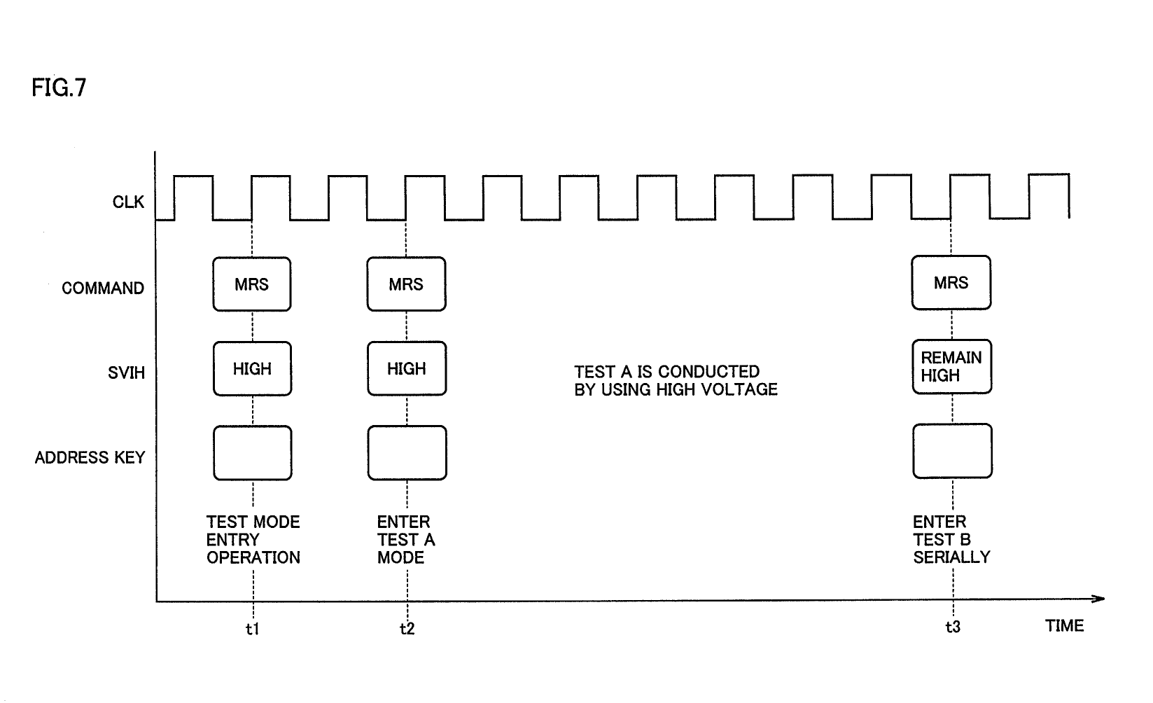

FIG. 7 is an operation waveform chart for explaining the test entry operation of the first embodiment.

Referring to FIG. 7, when the mode register command is given at the rising edge of clock signal CLK and signal SVIH is activated to a predetermined high potential at time t1, signal BA0S in FIG. 3 is activated. It makes the DRAM enter a test mode in accordance with the address key, that is, a state where a test mode can be set is obtained.

When the mode register set command is given at the rising edge of clock signal CLK and signal SVIH is set to a predetermined high potential at time t2, the DRAM can enter the test A mode by a combination of the address key.

The test A is a test conducted by using a high voltage. Consequently, external power supply potential EXVDD is increased to a high level beyond the normal operation standard range and a predetermined test is carried out.

Subsequently, when the mode register set command is given at the rising edge of clock signal CLK at time t3, in the case where external power supply potential EXVDD is at the high level beyond the normal operation standard range, TE1 in FIG. 3 is activated. Therefore, without applying a potential which is recognized as a high potential as signal SVIH, the DRAM can enter the test B mode by the mode register set command and the address key.

The threshold voltage of inverter 68 at this time has to be adjusted to be at a high level to a certain extent for the following reason. Since signal TENT is activated irrespective of the level of signal SVIH, only when at least external power supply potential EXVDD is at the high level beyond the normal operation standard range, it has to exceed the threshold value of inverter 68.

As described above, in a state where a reference potential as a reference of comparison applied to the SVIH comparing circuit, for example, the external power supply potential becomes very high, irrespective of the level of signal SVIH, signal TENT is output. It is equivalent that SVIH comparing circuit 52 recognizes that signal SVIH is at the high level.

Therefore, like in the conventional case where a test applying a high voltage or a test using an increased internal voltage is carried out, also under circumstances that another test mode cannot be set without applying the SVIH signal of a very high voltage, according to the first embodiment, a test mode can be set irrespective of signal SVIH. Thus, a test can be conducted easily with high efficiency.

Second Embodiment

A semiconductor device according to a second embodiment has a configuration similar to that of the semiconductor device of the first embodiment except that a test mode signal generating circuit 110 is included in place of test mode signal generating circuit 56 in FIG. 3.

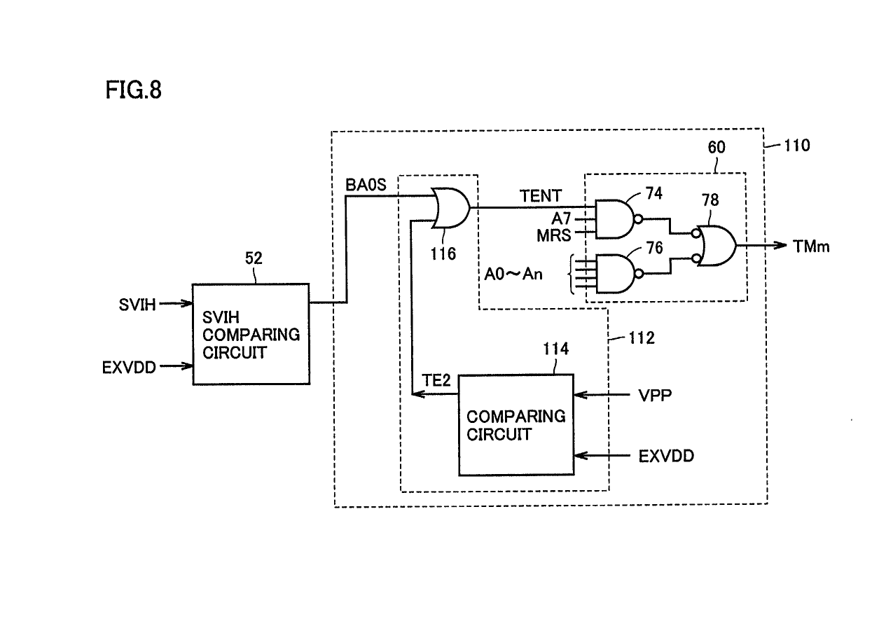

FIG. 8 is a circuit diagram showing the configuration of test mode signal generating circuit 110 of the second embodiment.

Referring to FIG. 8, test mode signal generating circuit 110 outputs test mode signal TMm in accordance with signal BA0S, external power supply potential EXVDD, and power supply potential VPP output from SVIH comparing circuit 52.

Test mode signal generating circuit 110 includes a test setting control unit 112 in place of test setting control unit 58 in the configuration of test mode signal generating circuit 56 shown in FIG. 3.

Test setting control unit 112 includes a comparing circuit 114 for outputting signal TE2 in accordance with power supply potential VPP and external power supply potential EXVDD, and an OR circuit 116 for receiving signals BA0S and TE2 and outputting signal TENT.

The comparison reference voltage for signal SVIH is used as external power supply potential EXVDD and the reference comparison potential for external power supply potential EXVDD is set as power supply potential VPP. Power supply potential VPP is a stabilized potential generated internally by voltage generating circuit 40 shown in FIG. 1. Power supply potential VPP is therefore maintained constant even in the case where external power supply potential EXVDD fluctuates.

When external power supply potential EXVDD is higher than a certain ratio of power supply potential VPP, comparing circuit 114 outputs a signal at the H level. In this case, irrespective of the output of SVIH comparing circuit 52, the test mode can be set.

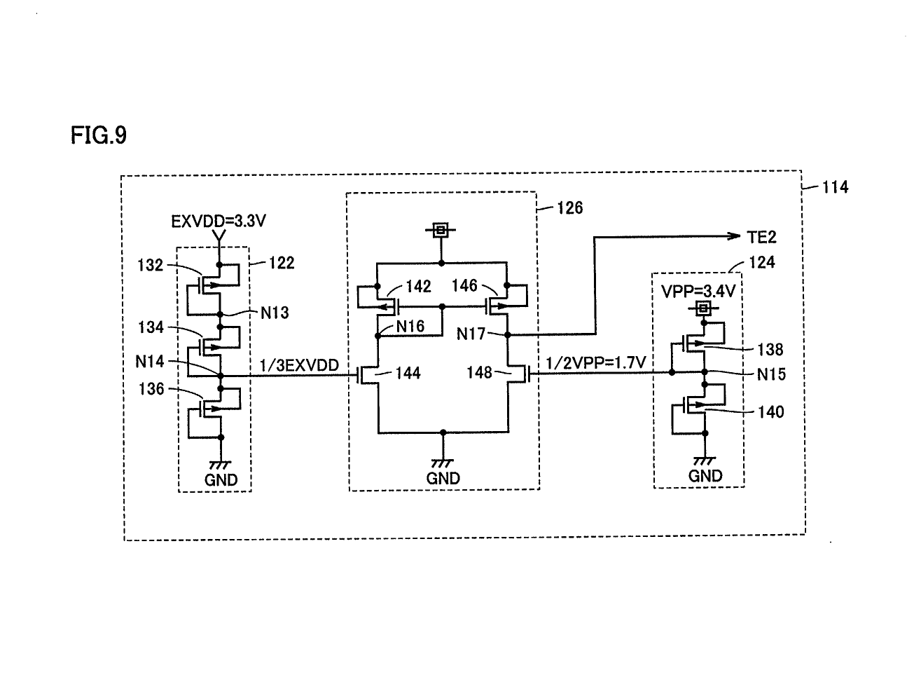

FIG. 9 is a circuit diagram showing the configuration of comparing circuit 114 in FIG. 8.

Referring to FIG. 9, comparing circuit 114 includes a potential down converting circuit 122 for receiving and dropping external power supply potential EXVDD and outputting signal 1/3EXVDD, a potential down converting circuit 124 for receiving and dropping power supply potential VPP and outputting signal 1/2VPP, and a comparing circuit 126 for comparing signals 1/3EXVDD and 1/2VPP and outputting comparison result signal TE2.

Potential down converting circuit 122 includes: a P-channel MOS transistor 132 having a source and a back gate connected to a node to which external power supply potential EXVDD is supplied and a gate and a drain connected to a node N13; a P-channel MOS transistor 134 having a source and a back gate connected to node N13 and a gate and a drain connected to a node N14; and a P-channel MOS transistor 136 having a source and a back gate connected to node N14 and a gate and a drain connected to a ground node. Signal 1/3EXVDD is output from node N14.

Potential down converting circuit 124 includes a P-channel MOS transistor 138 having a source and a back gate connected to a node to which power supply potential VPP is applied and a gate a and a drain connected to a node N15; and a P-channel MOS transistor 140 having a source and a back gate connected to node N15 and a gate and a drain connected to the ground node. Signal 1/2VPP is output from node N15.

Comparing circuit 126 includes: a P-channel MOS transistor 142 having a source and a back gate connected to the source node and a gate and a drain connected to a node N16; an N-channel MOS transistor 144 connected between node N16 and the ground node and receiving signal 1/3EXVDD by its gate; a P-channel MOS transistor 146 having a source and a back gate connected to the source node, a gate connected to node N16, and a drain connected to a node N17; and an N-channel MOS transistor 148 connected between node N17 and the ground node and receiving signal 1/2VPP by its gate.

Although FIG. 9 shows the circuit for dividing external power supply potential EXVDD to ⅓ and dividing power supply potential VPP to the half as an example of the potential down converting circuit, a dividing ratio of external power supply potential EXVDD and power supply potential VPP is determined according to the operation condition at the time of setting the test mode.

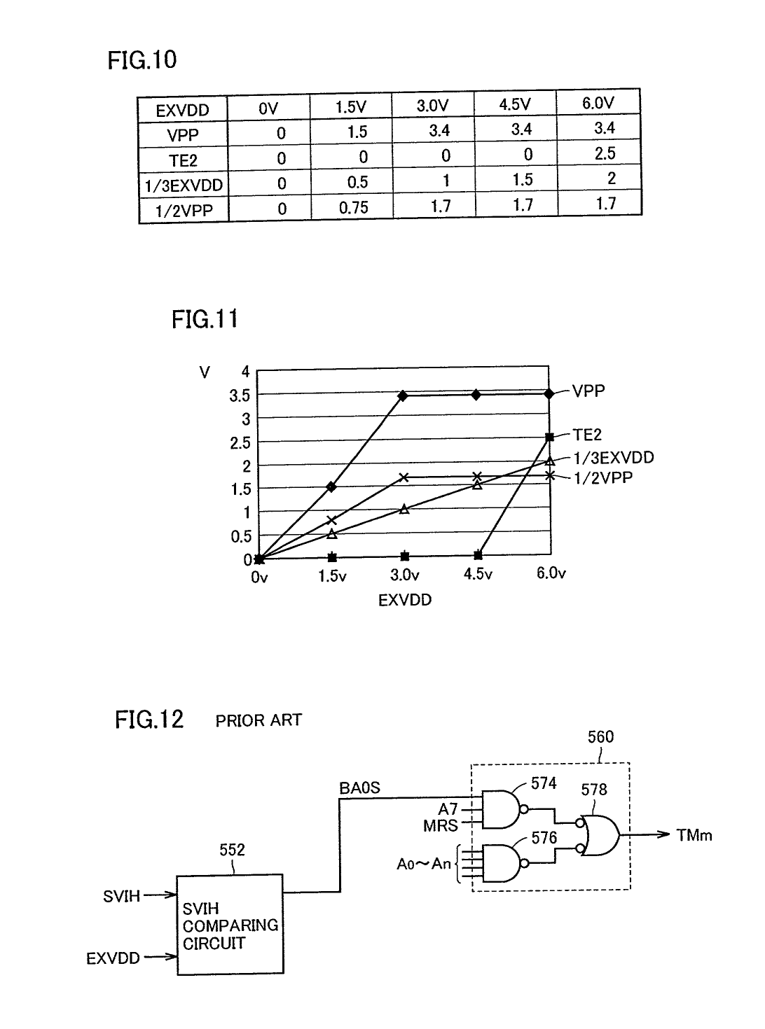

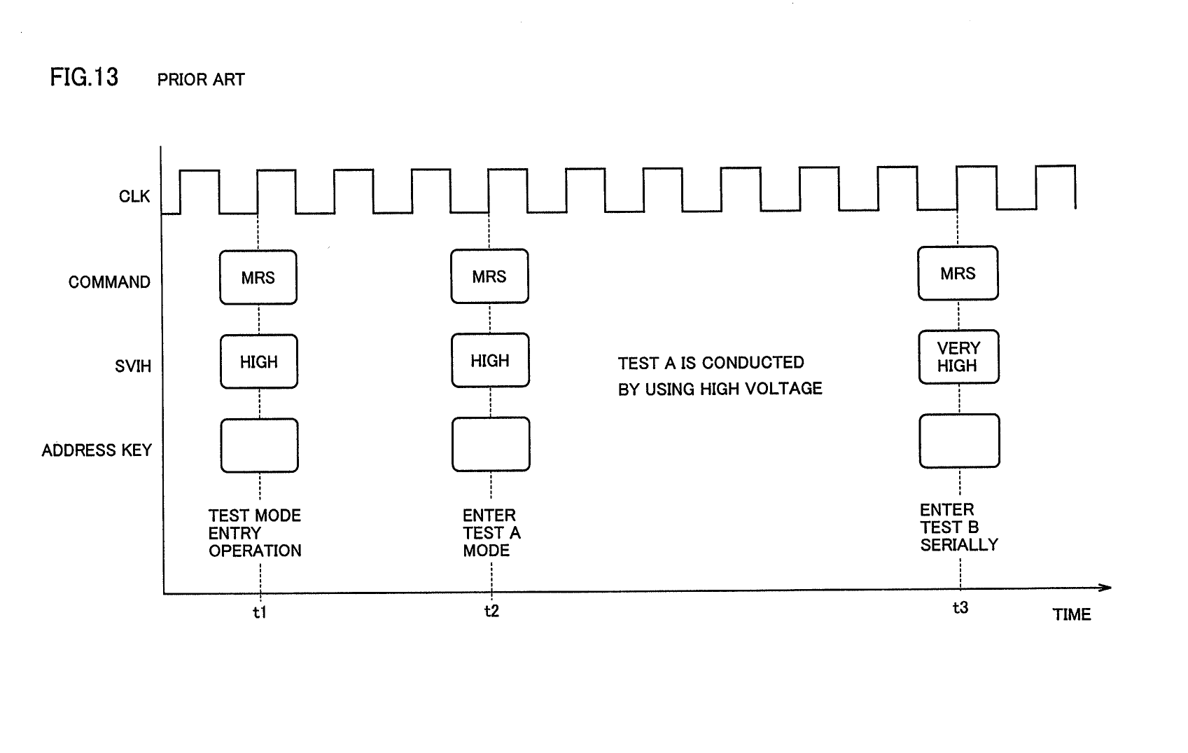

FIG. 10 is a diagram showing the levels of representative nodes in FIG. 9 in the case where external power supply potential EXVDD changes.

FIG. 11 is the plot of the voltages corresponding to those in FIG. 10.

Referring to FIGS. 10 and 11, when external power supply potential EXVDD is 0V, each of power supply potential VPP, signal TE2, signal 1/3EXVDD, and signal 1/2VPP is 0V.

When external power supply potential EXVDD becomes 1.5V, power supply potential VPP and signals TE2, 1/3EXVDD, and 1/2VPP become 1.5V, 0V, 0.5V, and 0.75V, respectively.

When external power supply potential EXVDD becomes 3.0V, power supply potential VPP and signals TE2, 1/3EXVDD, and 1/2VPP become 3.4V, 0V, 1V, and 1.7V, respectively.

When external power supply potential EXVDD is 4.5V, power supply potential VPP and signals TE2, 1/3EXVDD, and 1/2VPP become 3.4V, 0V, 1.5V, and 1.7V, respectively.

When external power supply potential EXVDD is 6.0V, power supply potential VPP is 3.4V and 1/2VPP is 1.7V. Since signal 1/3EXVDD is 2V, it is larger than signal 1/2VPP. Comparing circuit 126 therefore outputs 2.5V which is the H level. Specifically, when external power supply potential EXVDD is 6.0V, signal TE2 is set to the H level. A test mode can be consequently set without setting signal SVIH to a high potential.

The circuit of FIG. 9 compares, as an example, the potential which is ⅓ of external power supply potential EXVDD with the potential which is the half of power supply potential VPP. However, the dividing ratio is used by being changed according to a use state at the time of designing.

In the case of the dividing ratio, when external power supply potential EXVDD is sufficiently high, signal 1/2VPP is constant irrespective of external power supply potential EXVDD and is about 1.7V. In contrast, in the case where external power supply potential EXVDD changes, signal TE2 is activated to the H level when the relation of 1/3EXVDD>1/2VPP is satisfied, that is, when external power supply potential EXVDD becomes higher than 5.1V.

As described above, in the semiconductor device of the second embodiment as well, also during a test conducted by applying a high voltage or a test using an increased internal voltage, it is unnecessary to set signal SVIH to a very high voltage, and another test mode can be set. Thus, a test can be conducted easily with high efficiency.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device having a test mode and a normal mode as operation modes, comprising a test mode control circuit,
said test mode control circuit including:
a first comparing circuit for comparing a reference potential with a test mode setting potential supplied from the outside;
a test setting control unit for generating a test mode entry signal in accordance with an output of said first comparing circuit when said reference potential is lower than a predetermined potential, and generating said test mode entry signal irrespective of an output of said first comparing circuit when said reference potential is at least said predetermined potential; and
a test mode signal outputting circuit for outputting a test mode signal indicative of activation of a predetermined test operation in accordance with an output of said test setting control unit.

2. The semiconductor device according to claim 1, further comprising an internal power supply potential generating circuit for receiving an external power supply potential and generating a stabilized internal power supply potential,
wherein said test setting control unit includes:
a first potential down converting circuit for receiving said reference potential and outputting a potential lower than said reference potential;
an inverter for receiving an output of said potential down converting circuit as an input signal and receiving said internal power supply potential as an operation power supply potential; and
a gate circuit for outputting said test mode entry signal in accordance with an output of said inverter and an output of said first comparing circuit.

3. The semiconductor device according to claim 2, wherein said first potential down converting circuit has a plurality of voltage dividing devices connected in series between a node for receiving said reference potential and a ground node, and
said inverter receives, as said input signal, one of potentials of the connecting nodes of said plurality of voltage dividing devices.

4. The semiconductor device according to claim 2, wherein said first potential down converting circuit has a plurality of field effect transistors which are connected in series so as to form diodes between a node for receiving said reference potential and a ground node,
each of said plurality of field effect transistors has a back gate connected to a source, and
said inverter receives, as said input signal, a potential of one of the connecting nodes of said plurality of field effect transistors.

5. The semiconductor device according to claim 2, wherein said reference potential is equal to said external power supply potential.

6. The semiconductor device according to claim 1, further comprising an internal power supply potential generating circuit for receiving an external power supply potential and generating a stabilized internal power supply potential,
wherein said test setting control unit has
a first potential down converting circuit for receiving said reference potential and outputting a potential lower than said reference potential;
a second potential down converting circuit for receiving said internal power supply potential and outputting a potential lower than said internal power supply potential;
a second comparing circuit for comparing outputs of said first and second potential down converting circuits; and
a gate circuit for outputting said test mode entry signal in accordance with outputs of said first and second comparing circuits.

7. The semiconductor device according to claim 6, wherein said first potential down converting circuit has a plurality of first voltage dividing devices connected in series between a node for receiving said reference potential and a ground node,
said second potential down converting circuit has a plurality of second voltage dividing devices connected in series between a node for receiving said internal power supply potential and a ground node, and
said second comparing circuit compares a potential of one of the connecting nodes of said plurality of first voltage dividing devices and a potential of one of the connecting nodes of said plurality of second voltage dividing devices.

8. The semiconductor device according to claim 6, wherein said first potential down converting circuit has a plurality of first field effect transistors connected in series so as to form diodes between a node for receiving said reference potential and a ground node,
each of said plurality of field effect transistors has a back gate connected to a source,
said second potential down converting circuit has a plurality of second field effect transistors connected in series so as to form diodes between a node for receiving said internal power supply potential and the ground node,
each of said plurality of second field effect transistors has a back gate connected to a source, and
said second comparing circuit compares a potential of one of the connecting nodes of said plurality of first field effect transistors and a potential of one of the connecting nodes of said plurality of second field effect transistors.

9. The semiconductor device according to claim 6, wherein said reference potential is equal to said external power supply potential.

10. The semiconductor device according to claim 1, further comprising:
a memory array including a plurality of memory cells arranged in a matrix;
a row selecting circuit for selecting a row of said memory cells in accordance with an address signal; and
a column selecting circuit for selecting a column of said memory cells in accordance with said address signal,
said test mode output circuit having a gate circuit for decoding said address signal and outputting said test mode signal when said test entry signal is activated.
